(19) United States
(12) Patent Application Publication
(10) Pub. No.: US 2021/0363642 A1
(43) Pub. Date: Nov. 25, 2021

(54) Systems And Methods For Continuous Deposition

(71) Applicant: Redwire Space, Inc., Jacksonville, FL (US)

(72) Inventors: Patrick Flowers, Jacksonville, FL (US); Michael Snyder, Jacksonville, FL (US)

(21) Appl. No.: 17/238,878

(22) Filed: Apr. 23, 2021

Related U.S. Application Data
(60) Provisional application No. 63/028,476, filed on May 21, 2020.

(51) Int. Cl. C23C 16/54; C23C 16/448; C23C 16/52; C23C 16/04

(52) U.S. Cl. CPC C23C 16/54; C23C 16/4481; C23C 16/04; C23C 16/52; C23C 16/4485

(57) ABSTRACT

The present disclosure provides generally for deposition of a material onto a substrate. More specifically, the present disclosure relates to systems and methods for continuous deposition of coating onto a substrate with an actively replenished replenishing material source. In some aspects, the deposition process may occur in a vacuum environment. In some embodiments, the deposition process may occur on site, such as during installation or manufacturing. In some implementations, the deposition process may occur in micro or zero gravity, and the installation or manufacturing may occur in space.

### CROSS REFERENCE SECTION

This application claims priority to and the full benefit of U.S. Provisional Patent Application Ser. No. 63/028,476, filed May 21, 2020, and titled “SYSTEMS AND METHODS FOR CONTINUOUS DEPOSITION”, the entire contents of which are incorporated in this application by reference.

### BACKGROUND OF THE DISCLOSURE

Vapor deposition is a surface engineering treatment which deposits layers of materials onto a substrate. The materials may include metals (such as gold, titanium, or copper), as well as non-metals (such as silicon and carbon). Materials are vaporized and deposited atom-by-atom or molecule-by-molecule onto the substrate, creating a thin layer of the deposited material. The materials may be applied multiple times, allowing for a thicker layer, and may also be layered with multiple materials for different effects. When this process is completed in a vacuum, this allows the molecules to flow uniformly onto the substrate to create even layers.

Molecular deposition is used in many fields and for many purposes. Metal deposition may be used in additive manufacturing, allowing for the user to repair metallic components, such as tools, screws, valves, and more. Other professions may use the process to coat wires (such as with copper, gold, or aluminum) to promote conductivity or enhance corrosion resistance. The deposition of other materials may make the substrate hydrophobic, wear-resistant, or weather-resistant.

Deposition of gold molecules is particularly important for space-related technologies, as its qualities make it desirable to coat telescopic mirrors and other reflective materials. Gold does not oxidize, allowing the metal to exist perpetually without tarnishing or altering in other ways over time (as opposed to aluminum rusting). Gold is also an excellent material for reflecting infrared wavelengths of light. This allows for detection of celestial objects at further distances than other materials would permit.

Vapor deposition system machines are typically around the size of a standard refrigerator, if not larger. While larger laboratories may face no issues housing such equipment, not everyone has unlimited space or weight constraints. For example, in-space manufacturers must be intentional with each inch and each pound of materials that are brought on board. Heavier equipment than permitted could, at times, be the difference between life and death when traveling from Earth into space.

Finally, the current deposition process requires manual re-filling of the materials. The process of replacing the materials may not only be time consuming, but the materials may become empty in the middle of coating a specific substrate, which could interfere with the efficacy of the final product. Further, if the material must be replaced frequently, this may mean that the extra materials are taking up additional space. Lastly, each time materials are manually replenished contaminants may be introduced that can significantly impact the performance and efficacy of the coating.

### SUMMARY OF THE DISCLOSURE

What is needed is a convenient deposition process that limits the need for manual replacement and replenishment of supply. Accordingly, the present disclosure relates to systems and methods for continuous deposition of coating onto a substrate with an actively replenished material source. In some aspects, the deposition process may occur in a vacuum environment. In some embodiments, the deposition process may occur on site, such as during installation or manufacturing. In some implementations, the deposition process may occur in micro or zero gravity, and the installation or manufacturing may occur in space.

In some aspects, the system may coat a beam in a thin layer of gold using a gold coated wire feedstock as the gold source. In some embodiments, coatings may allow components to support the thermal and electrical requirements of a system and environment. Coating beams with gold may allow for a high electrical conductivity to minimize electrostatic discharging events, which may damage some components. In some implementations, a beam may be exposed to thermal gradients affecting warping of the beam. A low emissivity coating of gold on the hot side of the beam may mitigate this issue. Some implementations of the described techniques may comprise hardware, a method or process, or computer software on a computer-accessible medium.

In some embodiments, the present disclosure relates to a system for continuous deposition. The system includes a replenishing material source, where vaporization of at least a portion of the replenishing material source creates a coating material; a vaporization mechanism configured to vaporize at least the portion of the replenishing material source into the coating material; a controller configured to guide the replenishing material source through the vaporization mechanism; and a power supply configured to power the vaporization mechanism, where vaporization may be continuous with the power supply.

In some implementations, vaporization may cause the coating material to coat at least one substrate within a predefined proximity to the replenishing material source. In some aspects, the system may comprise at least one substrate rail configured to maintain a position of the at least one substrate. In some embodiments, the power supply may be further configured to power the controller. In some implementations, at least a portion of the system may be located within a vacuum environment. In some aspects, the coating material may comprise a plurality of coating material types. In some embodiments, the coating of the plurality of coating material types onto at least one substrate may comprise a sequence of layering administered to the at least one substrate sequentially. In some aspects, the system may be mobile. In some embodiments, the system may be handheld.

In some embodiments, the present disclosure relates to a method for continuous deposition. In some implementations, the method includes connecting a replenishing material source to a positive terminal; connecting the replenishing material source to a negative terminal; applying voltage to the replenishing material source, where the voltage passes from the positive terminal to the negative terminal; driving the replenishing material source across the positive terminal and the negative terminal; vaporizing at least a portion of the replenishing material source into a coating material; and coating a substrate with the coating material, where the substrate may be located in a predefined proximity to the replenishing material source.

In some aspects, the replenishing material source may originate from a spool. In some embodiments, vaporizing the at least the portion of the replenishing material source may be continuous with driving the replenishing material source across the positive terminal and the negative terminal. In some implementations, the method may comprise mounting the substrate within the predefined proximity to the replenishing material source. In some aspects, coating the substrate may occur at a predefined area of the substrate. In some embodiments, the method may comprise moving the substrate to coat the predefined area. In some implementations, the vaporization may occur within a vacuum. In some aspects, one or both connecting to the positive terminal and connecting to the negative terminal may occur indirectly. In some embodiments, one or both connecting to the positive terminal and connecting to the negative terminal may occur directly. In some implementations, the method may comprise replenishing the replenishing material source. In some aspects, replenishing the replenishing material source may be continuous.

### BRIEF DESCRIPTION OF THE DRAWINGS

The accompanying drawings that are incorporated in and constitute a part of this specification illustrate several embodiments of the disclosure and, together with the description, serve to explain the principles of the disclosure:

FIG. 1 illustrates an exemplary continuous deposition system comprising a replenishing material source, according to some embodiments of the present disclosure.

FIG. 2A illustrates an exemplary continuous deposition system comprising one or more replenishing material sources, according to some embodiments of the present disclosure.

FIG. 2B illustrates an exemplary continuous deposition system comprising one or more replenishing material sources, according to some embodiments of the present disclosure.

FIG. 3 illustrates an exemplary continuous deposition system comprising an interchangeable replenishing material source, according to some embodiments of the present disclosure.

FIG. 4A illustrates an exemplary continuous deposition system comprising a substrate and a plurality of replenishing material source, according to some embodiments of the present disclosure.

FIG. 4B illustrates an exemplary continuous deposition system comprising a substrate and a plurality of replenishing material source, according to some embodiments of the present disclosure.

FIG. 4C illustrates an exemplary continuous deposition system comprising a substrate and a plurality of replenishing material source, according to some embodiments of the present disclosure.

FIG. 4D illustrates an exemplary continuous deposition system comprising a substrate and a plurality of replenishing material source, according to some embodiments of the present disclosure.

FIG. 5 illustrates an exemplary continuous deposition system comprising a replenishing material source, according to some embodiments of the present disclosure.

FIG. 6 illustrates an exemplary continuous deposition system comprising a replenishing material source and one or more sensors, according to some embodiments of the present disclosure.

to FIG. 7 illustrates an exemplary continuous deposition system comprising a replenishing material source and a plurality of sensors, according to some embodiments of the present disclosure.

FIG. 8A illustrates an exemplary continuous deposition system comprising a replenishing material source, according to some embodiments of the present disclosure.

FIG. 8B illustrates an exemplary continuous deposition system comprising a replenishing material source, according to some embodiments of the present disclosure.

FIG. 9A illustrates an exemplary continuous deposition system comprising a replenishing material source, according to some embodiments of the present disclosure.

FIG. 9B illustrates an exemplary continuous deposition system comprising a plurality of substrate and a plurality of replenishing material source, according to some embodiments of the present disclosure.

FIG. 9C illustrates an exemplary substrate surface with variable coating material, according to some embodiments of the present disclosure.

FIG. 10 illustrates an exemplary continuous deposition system comprising a replenishing material source, according to some embodiments of the present disclosure.

FIG. 11 illustrates an exemplary continuous deposition system comprising a replenishing material source, according to some embodiments of the present disclosure.

FIG. 12A illustrates an exemplary continuous deposition system comprising a replenishing material source, according to some embodiments of the present disclosure.

FIG. 12B illustrates a perspective view of an exemplary continuous deposition system comprising a replenishing material source, according to some embodiments of the present disclosure.

FIG. 12C illustrates a side view of an exemplary continuous deposition system comprising a replenishing material source, according to some embodiments of the present disclosure.

FIG. 13A illustrates an exemplary continuous deposition system comprising a rotational replenishing material source, according to some embodiments of the present disclosure.

FIG. 13B illustrates an exemplary continuous deposition system comprising a rotational replenishing material source, according to some embodiments of the present disclosure.

FIG. 14 illustrates an exemplary mobile continuous deposition system, according to some embodiments of the present disclosure.

FIG. 15 illustrates a portable exemplary continuous deposition system, according to some embodiments of the present disclosure.

FIG. 16 illustrates exemplary method steps for continuous deposition of material onto a substrate.

### DETAILED DESCRIPTION

The present disclosure provides generally for deposition of a material onto a substrate. More specifically, the present disclosure relates to systems and methods for continuous deposition of coating onto a substrate with an actively replenished replenishing material source. In some aspects, the deposition process may occur in a vacuum environment. In some embodiments, the deposition process may occur on site, such as during installation or manufacturing. In some implementations, the deposition process may occur in micro or zero gravity, and the installation or manufacturing may occur in space.

In the following sections, detailed descriptions of examples and methods of the disclosure will be given. The description of both preferred and alternative examples, though thorough, are exemplary only, and it is understood to those skilled in the art that variations, modifications, and alterations may be apparent. It is therefore to be understood that the examples do not limit the broadness of the aspects of the underlying disclosure as defined by the claims.

### Glossary

Continuous Deposition: as used herein refers to the process of coating a substrate through vaporization of coating from a source material. Continuous refers to continued vaporization as source material is moved through a continuous deposition system. This is in contrast to traditional deposition, which is generally static.
Replenishing Source Material: as used herein refers to source material that may be replenished as the source material travels through the continuous deposition system to allow for continuous deposition. In some aspects, replenishing source material may originate from a spool or other mechanism that may be unraveled. In some embodiments, replenishing source material may comprise a plurality of source material pellets that may be dropped into the continuous deposition system. In some implementations, replenishing source material may limit interruptions in deposition.
Substrate: as used herein refers to any substance, object, or material that may be coated through continuous deposition. In some aspects, a substrate may be fixed in position as it is coated. In some embodiments, a substrate may be movable as it is coated.
Vaporization Mechanism: as used herein refers to a mechanism utilized to facilitate the transition of the replenishing material source into coating material. In some embodiments, the vaporization mechanism may comprise a heating mechanism. In some implementations, the vaporization mechanism may comprise a voltage. In some aspects, the voltage may originate from a power supply.

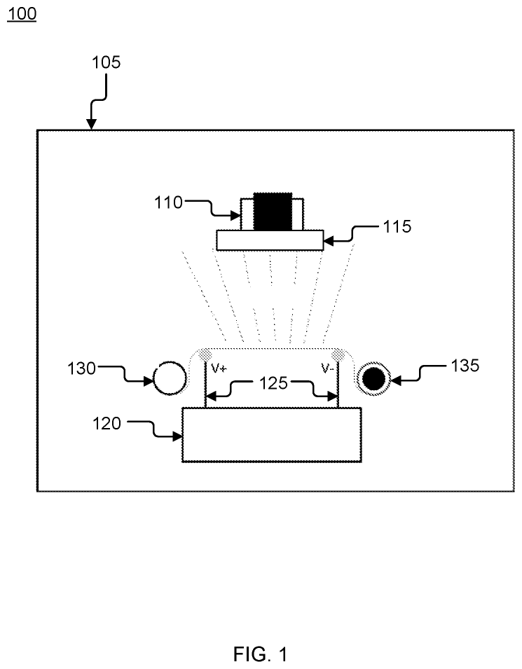

Referring now to FIG. 1, an exemplary continuous deposition system 100 comprising a replenishing material source 130 is illustrated. In some aspects, a continuous deposition system 100 may utilize evaporative deposition, wherein replenishing material source 130 may be heated to a high vapor pressure through electrically resistive heating. In some embodiments, a sublimation type of vaporization process may be used. In some implementations, the continuous deposition system 100 may operate within a controlled environment 105, such as a vacuum chamber. In some aspects, evaporative deposition may be performed in a low vacuum, which may limit contamination.

In some embodiments, a substrate 115 may be attached to a linear rail 110, wherein the linear rail 110 may move the substrate along a path, allowing for coating of the entire intended surface. In some implementations, replenishing material source 130 may comprise a spool, which may allow for a continuous deposition process with limited need to replace the replenishing material source 130. In some aspects, the replenishing material source 130 may be connected to positive and negative terminals 125 of a power supply 120, wherein electrical heating may cause the coating material to evaporate.

In some embodiments, the replenishing material source 130 may be connected to a controller 135 that may actively drive the replenishing material source 130 through the terminals 125. For example, where the replenishing material source 130 comprises a wire or flexible material, the controller 135 may comprise a motorized spool that may simultaneously drive the replenishing material source 130 and collect used portions. In some aspects, the replenishing material source 130 may be maintained as a predefined temperature and pressure. In some embodiments, a replenishing material source 130 that is actively replenished may allow for continuous deposition without requiring constant replacement. Active replenishment may create an efficient use of space, allowing for a smaller footprint for the chamber 105.

As an illustrative example, two copper posts 125 may be connected to the positive and negative terminals of a power supply 120. A polyetherimide substrate 115 may be mounted to a linear rail 110 suspended above the posts 125. A piece of Kapton tape may be affixed to the polyetherimide substrate 115. Voltage may be applied to the posts 125 and a DC motor 135 may be used to drive corona wire (tungsten wire coated in gold) 130 across the two copper posts 125 as the polyetherimide substrate 115 is moved back and forth. After completion, the Kapton tape may be removed.

In some aspects, the temperature of the wire may be set to 1050 C or just below the melting temperature of gold. The vapor pressure of gold at this temperature is 1.2E-5 torr, wherein heating the wire above 1050 C and keeping the chamber pressure below 1.2E-5 torr rapidly vaporizes the gold and coats the surface of anything within line of sight of the replenishing material source 130. In some embodiments, the temperature of the wire may be reduced or the chamber pressure may be increased to control the deposition rate, as non-limiting alternatives, when a slower deposition is desired. In some aspects, the temperature of the replenishing material source 130 may be maintained with a low power supply, which may allow for sustained and continuous deposition as the replenishing material source 130 is replenished.

In some implementations, the continuous deposition system 100 may comprise a connection between a replenishing material source 130 and a positive terminal. In some aspects, the continuous deposition system may connect the replenishing material source to a negative terminal. In some embodiments, the continuous deposition system may apply voltage from a power supply 120 to a replenishing material source 130, wherein the voltage may pass from the positive terminal to the negative terminal.

In some implementations, the continuous deposition system 100 may drive the replenishing material source 130 across the positive terminal and the negative terminal. In some aspects, the continuous deposition system may vaporize at least a portion of the replenishing material source 130 into a coating material. In some embodiments, the continuous deposition system 100 may coat a substrate 115 with the coating material, wherein the substrate 115 is located in a predefined proximity to the replenishing material source 130.

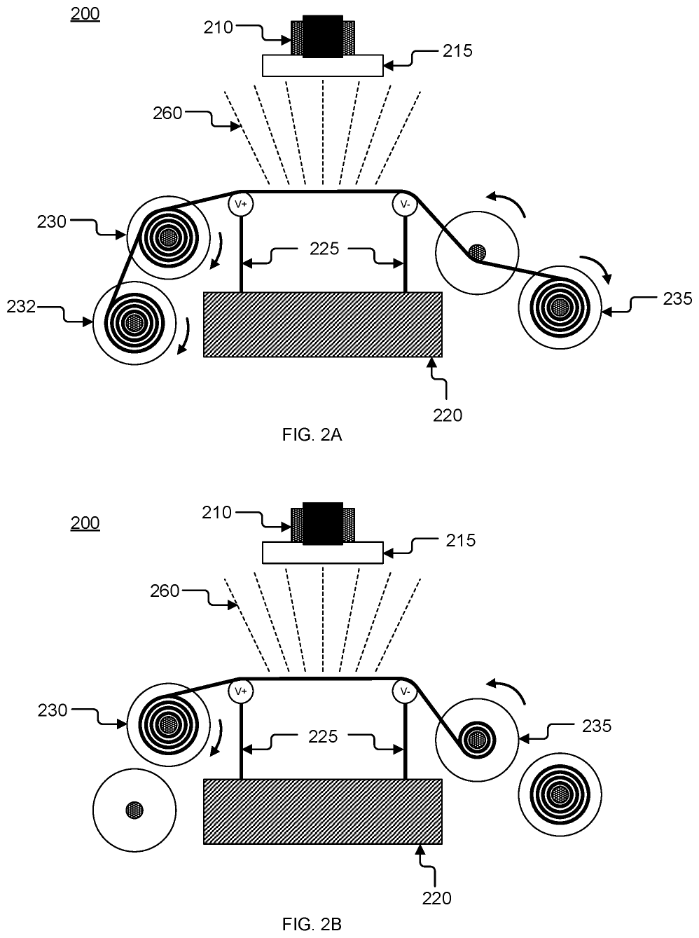

Referring now to FIGS. 2A-2B, an exemplary continuous deposition system 200 comprising one or more material sources 230, 232 is illustrated. In some embodiments, the continuous deposition system 200 may comprise a rail 210. In some aspects, the rail 210 may be fixed. This may be useful when the intended substrate 215 is consistently the same size and composition. In some embodiments, the rail 210 may be positioned prior to the attachment of a substrate. In some aspects, the positioning of the rail 210 may be configured in relation to the most effective distance for coating the substrate 215.

In some implementations, the rail 210 may comprise the substrate 215. In some embodiments, the continuous deposition system 200 may receive coating material 260 from one or more replenishing material sources 230, 232. In some implementations, the continuous deposition system 200 may receive coating material 260 from replenishing material sources 230, 232 sequentially. For example, although there are two spools of coating material 260, one of the replenishing material sources 232 may not begin replenishing the coating material 260 until the other replenishing material source 230 is depleted.

In some aspects, the replenishing material sources may distribute coating material 260 in predetermined concentrations simultaneously. As an illustrative example, a substrate 215 may require a composite coating comprising gold and zinc for different properties such as heating coefficients and conductivity. The replenishing material source 232 containing zinc may contain less ions per unit length to form a predetermined composition of unequal parts when the gold and zinc fuse to form the coating on the substrate 215.

In some embodiments, particles of the coating material may be excited via electrical terminals 225 that receive power from a power supply 220. In some implementations, the coating material 260 may be replaceable upon depletion in a continuous method. In some aspects, the replenishing aspect of the coating material 260 may be facilitated by a controller 235. In some embodiments, the coating material 260 may be under tension to ensure a connection with the terminals 225.

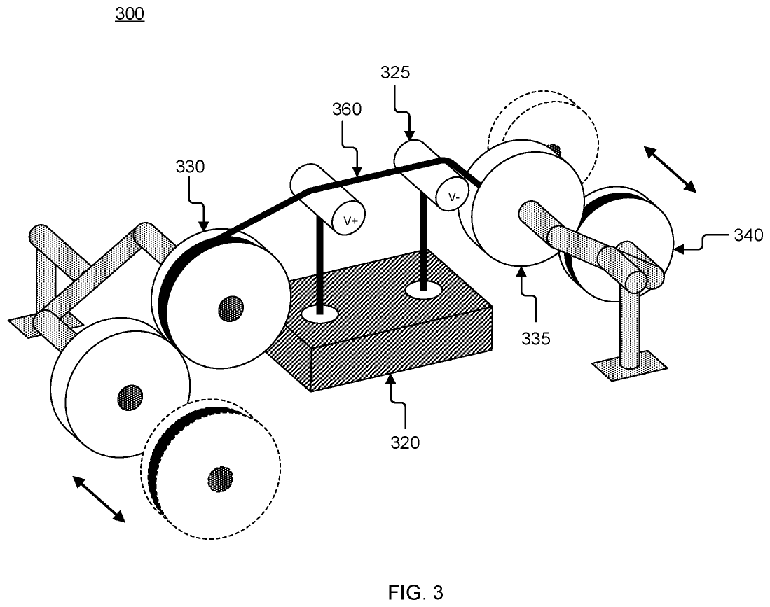

Referring now to FIG. 3, an exemplary continuous deposition system 300 comprising an interchangeable replenishing material source is illustrated. In some aspects, the continuous deposition system 300 may receive coating material 360 from one or more replenishing material sources 330. In some implementations, the coating material 360 may be continuously supplied by rotating a replenishing material source 330.

As an example, a stand with a plurality of arms may hold a plurality of spools of coating material 360. Each arm may comprise a controller 335, 340 which may facilitate a continuous feed of coating material 360 by rotating the distribution from a depleted replenishing material source 330 to another replenishing material source. As the distribution of the coating material changes from one arm of the replenishing material source 330 to another, the respective controllers 335, 340 may deactivate and activate to continue the distribution of the coating material 360. In some aspects, the deactivation and activation of the correct controller 335, 340 may be electronically synchronized sufficient to prevent an interrupt in the continuous feed of the coating material 360 from the replenishing material source 330.

In some embodiments, particles of the coating material 360 may be excited via electrical terminals 325 that receive power from a power supply 320, wherein the electrical terminals 325 may comprise at least a portion of the vaporization mechanism. In some implementations, the coating material may be replaceable upon depletion in a continuous method. In some aspects, the replenishing aspect of the coating material may be facilitated by a controller 335. In some embodiments, the coating material 360 may be replaced in fixed quantities.

As an example, the replenishing material source 330 may comprise a plurality of spools containing coating material 360 that may be replaced when the coating material 360 is depleted. The replacement of depleted spools may occur via an automated robotic arm that is notified when a spool is empty by an embedded sensor within the arm of the stand.

In some embodiments, the continuous deposition system 300 may comprise a replenishing material source 330, wherein vaporization of at least a portion of the replenishing material source 330 creates a coating material 360. In some implementations, the continuous deposition system 300 may comprise a vaporization mechanism configured to vaporize at least a portion of the replenishing material source 330 into coating material 360. In some aspects, the continuous deposition system 300 may comprise a controller 335 configured to guide the replenishing material source 330 through the vaporization mechanism. In some embodiments, the continuous deposition system 300 may comprise a power supply 320 configured to power the vaporization mechanism, wherein vaporization is continuous with the power supply 320.

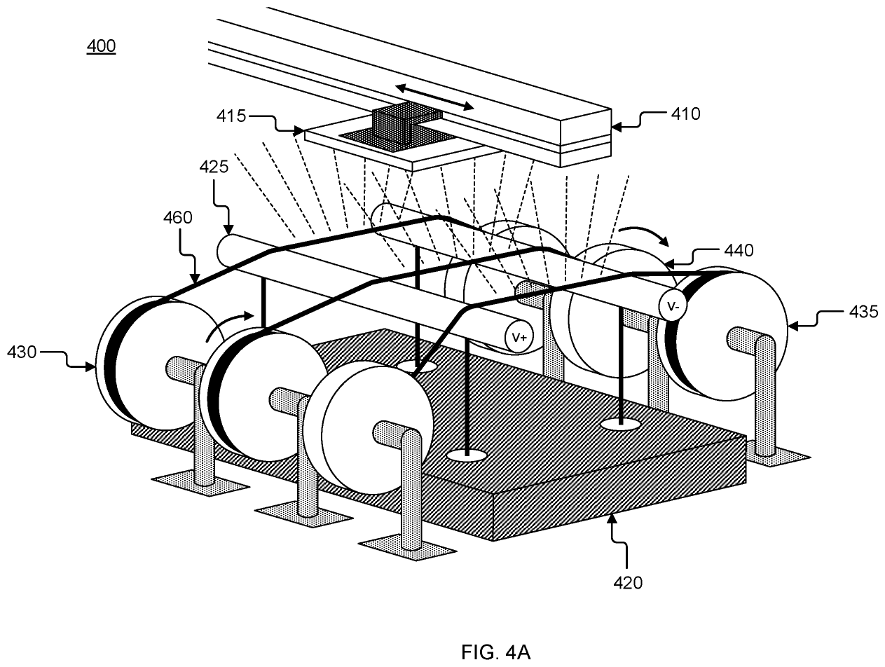

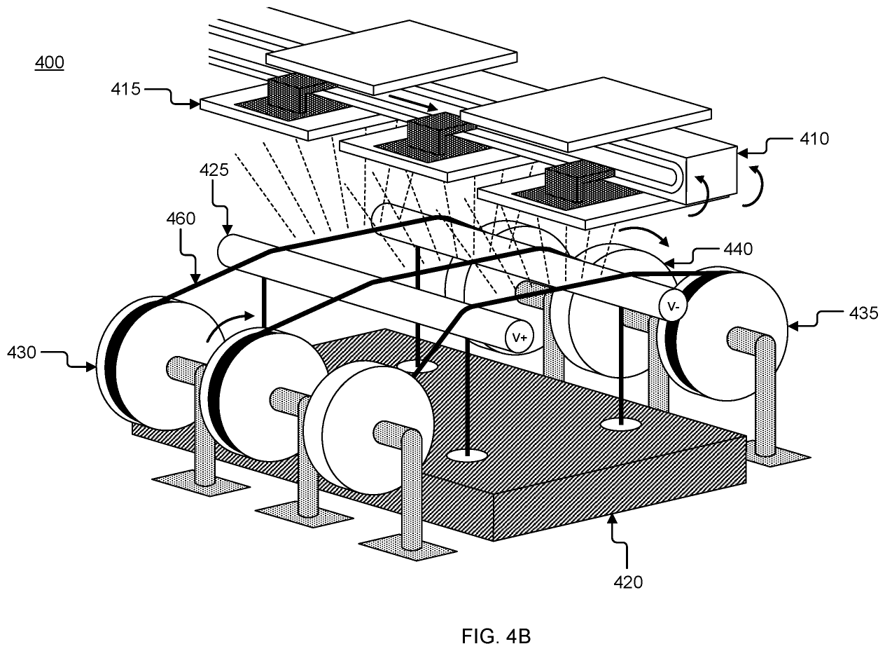

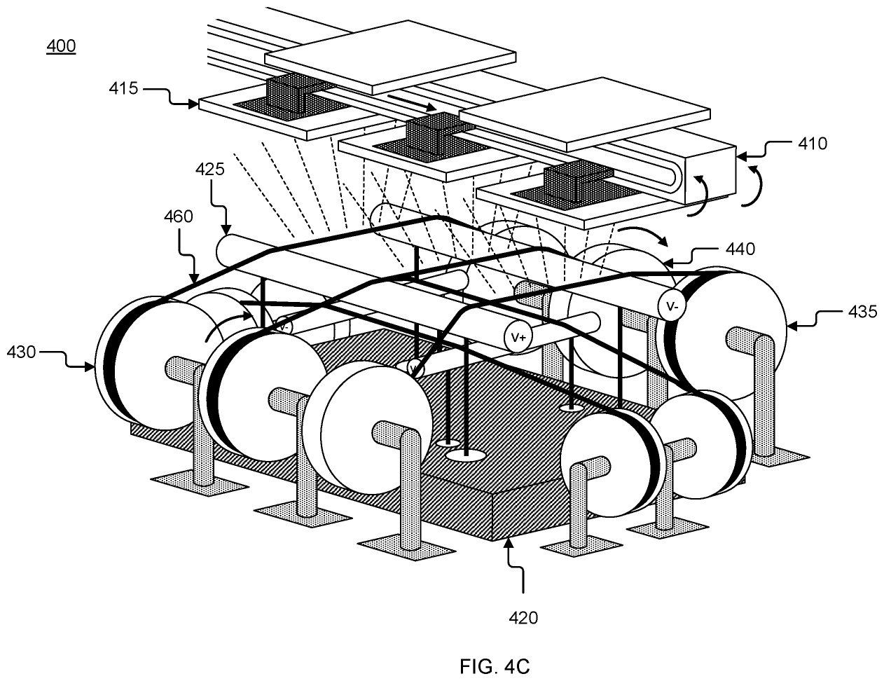

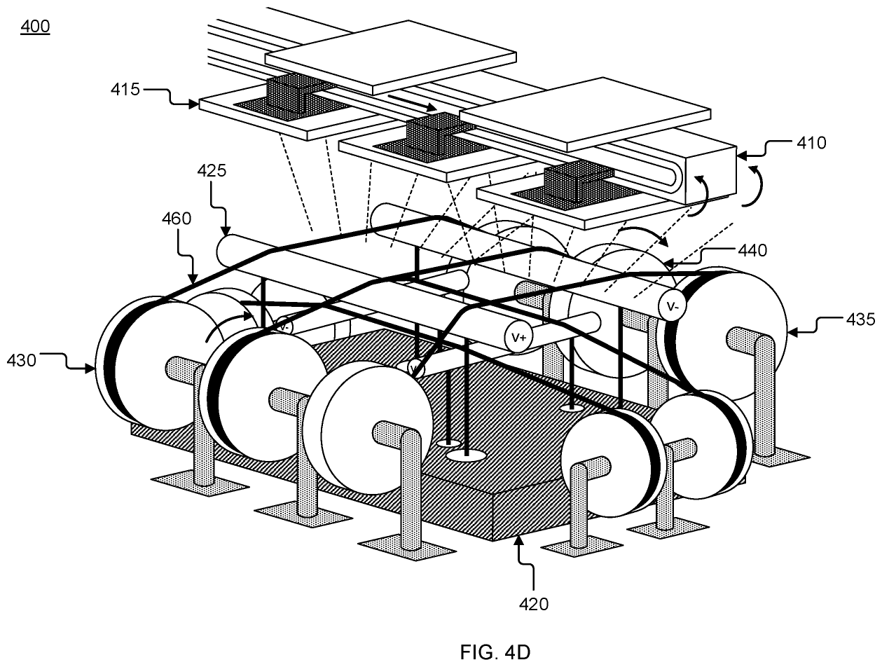

Referring now to FIG. 4A, an exemplary continuous deposition system 400 comprising a substrate 415 and a plurality of replenishing material source 430 is illustrated. In some embodiments, the continuous deposition system 400 may comprise a rail 410. In some implementations, the rail 410 may comprise the substrate 415. In some aspects, the continuous deposition system 400 may receive coating material 460 from one or more replenishing material sources 430. In some embodiments, particles of the coating material 460 may be excited via electrical terminals 425 that receive power from a power supply 420.

In some implementations, the coating material 460 may be emitted from a different region, upon depletion, in a continuous method. In some aspects, the replenishing aspect of the coating material may be facilitated by a plurality of controllers 435, 440. In some embodiments, the continuous deposition system 400 may receive coating material 460 from a plurality of replenishing material sources 430. In some implementations, the coating material 460 may be continuously supplied by alternating between available coating material 460 regions.

As an example, a plurality of spools of coating material 460 may be aligned in parallel. Each spool may comprise a controller 435, 440 which may facilitate a continuous feed of coating material 460 by ceasing rotation from a depleted replenishing material source 430 to activating the controller of another replenishing material source 430. As the distribution of the coating material 460 shifts from one spool of the replenishing material source 430 to another, the rail may allow linear translation to align the substrate 415 with the active region of the replenishing material source 430. In some aspects, the deactivation and activation of the correct controller 435, 440 may be electronically synchronized sufficient to prevent an interrupt in the continuous feed of the coating material 460 from the replenishing material source 430.

As an example, the replenishing material source 430 may comprise a plurality of spools containing coating material 460 that may be replaced when the coating material 460 is depleted. The replacement of depleted spools may occur via an automated robotic arm that is notified when a spool is empty by an embedded sensor within the arm of the stand. This sensor may also notify the rail to translate to the next active spool of coating material 460.

In some embodiments, a large substrate 415 may utilize a replenishing material source 430 that may coat a larger surface area. In some implementations, the replenishing material source 430 may comprise multiple regions of coating material 460. For example, a large substrate 415 may possess a sufficient surface area that three spools of coating material 460 placed in parallel are effective at distributing an even coating to the large surface area of the substrate 415 by operating simultaneously.

Referring now to FIGS. 4B-4D, an exemplary continuous deposition system 400 comprising a plurality of substrate 415 and a plurality of replenishing material source 430 is illustrated. In some embodiments, the continuous deposition system 400 may comprise a rail 410. In some implementations, the rail 410 may comprise one or more substrate 415. In some aspects, the continuous deposition system 400 may receive coating material 460 from one or more replenishing material sources 430.

As an illustrative example, substrates 415 may be attached to a plurality of securing points on the rail 410 prior to exposure to the coating material 460. When the substrate 415 is coated, the substrate may continue in rotational translation that brings to substrate 415 to the original attachment location to be replaced by another substrate 415. The replacement of the substrate 415 may occur continuously in cycles. In some aspects, the substrate 415 may comprise a continuous material.

As an illustrative example, a continuous sheet of satellite paneling may receive a coating via the continuous deposition system 400 prior to cutting and segmenting the spool of paneling to attach to the satellite. The coated paneling may be rolled onto a second spool for storage prior to segmentation. In some embodiments, the substrate 415 may be coating with a plurality of coating material 460.

For example, a composite coating may comprise aluminum and gold particles that may be applied to the substrate 415 simultaneously to allow for bonding and intermixing between the elements prior to the coating drying. As another example, the substrate 415 may receive a layer of coating for enhancing adhesion to the substrate and then a layer of gold coating for thermal conductivity properties.

In some aspects, the continuous deposition system 400 may receive coating material 460 from one or more replenishing material sources 430. In some embodiments, particles of the coating material 460 may be excited via electrical terminals 425 that receive power from a power supply 420. In some aspects, a plurality of spools of coating material 460 may be aligned in parallel. In some embodiments, a large substrate 415 may utilize a replenishing material source 430 that may coat a larger surface area. In some implementations, the replenishing material source 430 may comprise multiple regions of coating material 460. For example, a large substrate 415 may possess a sufficient surface area that three spools of coating material 460 placed in parallel are effective at distributing an even coating to the large surface area of the substrate 415 by operating simultaneously.

In some embodiments, particles of the coating material 460 may be excited via electrical terminals 425 that receive power from a power supply 420. As an example, a plurality of spools of coating material 460 may be aligned in parallel. In some embodiments, a large substrate 415 may utilize a replenishing material source 430 that may coat a larger surface area.

In some implementations, the replenishing material source 430 may comprise multiple regions of coating material 460. For example, a large substrate 415 may possess a sufficient surface area that three spools of coating material 460 placed in parallel are effective at distributing an even coating to the large surface area of the substrate 415 by operating simultaneously.

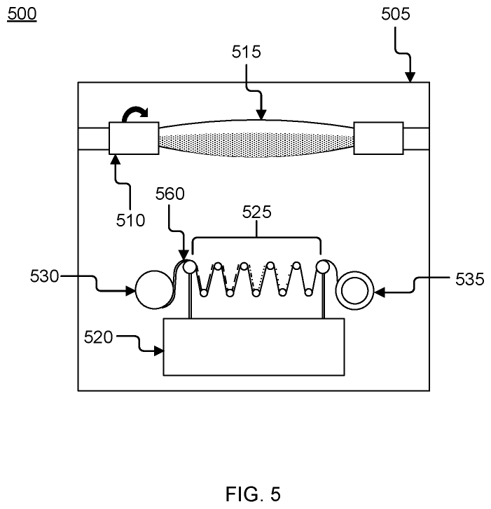

Referring now to FIG. 5, an exemplary continuous deposition system 500 comprising a replenishing material source 530 is illustrated. In some aspects, a continuous deposition system 500 may comprise a controlled environment chamber 505. In some embodiments, a substrate 515 may be attached to a rotating controller 510, wherein the rotating controller 510 may rotate the substrate 515 for complete coating.

In some embodiments, replenishing material source 530 may be driven through the positive and negative posts. In some aspects, the geometry of the driven replenishing material source 530 may be manipulated and controlled, which may create an asymmetric deposition allowing for more precise coating of a substrate 515. For example, the geometry may be manipulated through mechanical structures, such as a series of pullies 525. As another example, the voltage may be fluctuated through adjusting the power supply 520. As another example, the speed of driving the replenishing material source 530 may be varied, such as by adjusting the speed of a replenishing material source controller 535.

In some aspects, a predefined wattage may be required to maintain a wire temperature at steady state, which may be determined by calculating radiating heat losses on the wire at those temperatures. As an illustrative example, given a wire temperature of 1100 C, a wire diameter of 80 microns, and a wire length of 100 mm, only 5.1 watts of heat may be radiating from the surface. This may allow for reasonable power consumption at steady state.

In some implementations, the continuous deposition system 500 may comprise a connection between a replenishing material source 530 and a positive terminal. In some aspects, the continuous deposition system 500 may connect the replenishing material source 530 to a negative terminal. In some embodiments, the continuous deposition system 500 may apply voltage from a power supply 520 to a replenishing material source 530, wherein the voltage may pass from the positive terminal to the negative terminal.

In some implementations, the continuous deposition system 500 may drive the replenishing material source 530 across the positive terminal and the negative terminal. In some aspects, the continuous deposition system 500 may vaporize at least a portion of the replenishing material source 530 into a coating material 560. In some embodiments, the continuous deposition system 500 may coat a substrate 515 with the coating material 560, wherein the substrate 515 is located in a predefined proximity to the replenishing material source 530.

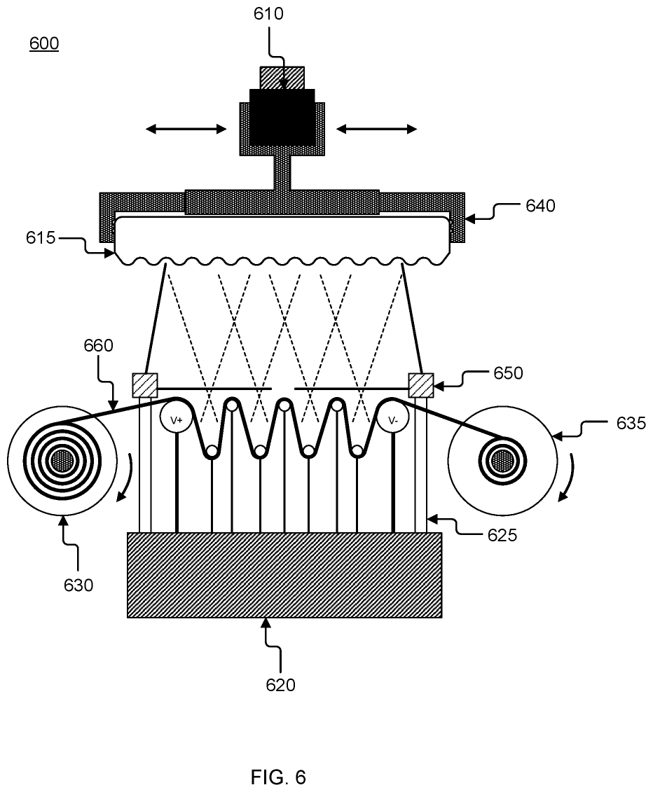

Referring now to FIG. 6, an exemplary continuous deposition system 600 comprising a replenishing material source 630 and one or more sensors 650 is illustrated. In some embodiments, the continuous deposition system 600 may comprise a rail 610. In some aspects, the rail 610 may move to ensure substrate 615 surface areas greater than the effective coating radius of the continuous deposition system 600 are coated sufficiently. In some implementations, the rail 610 may comprise the substrate 615. In some embodiments, a substrate holder 640 may secure the substrate 615 to the rail 610.

In some aspects, the continuous deposition system 600 may receive coating material 660 from a replenishing material source 630. In some implementations, the charged path of the coating material 660 between the terminals 625 may comprise a series of inclines and declines, as non-limiting examples. This variation in the angle of particle emission may allow uneven surfaces on the substrate to become sufficiently coated with the coating material 660.

In some embodiments, particles of the coating material may be excited via electrical terminals 625 that receive power from a power supply 620. In some implementations, the coating material 660 may be replaceable upon depletion in a continuous method. In some aspects, the replenishing aspect of the coating material 660 may be facilitated by a controller 635. In some embodiments, the distance between the substrate 615 and the coating material 660 may be determined by one or more sensors 650.

In some implementations, the sensors 650 may control the activation of the continuous deposition system 600. As an illustrative example, the sensors 650 may measure the height between the substrate 615 and the coating material 660. As the substrate 615 is within the effective radius of the coating material 660, the sensors 650 may activate the terminals 625 and the controller 635. The sensors 650 may comprise several sensors. One of these sensors 650 may monitor the temperature of the coating material 660. When the coating material 660 reaches the optimal temperature to begin transmitting the coating material 660 to the substrate 615, the sensors 650 may activate the controller 635.

In some embodiments, the sensors 650 may be calibrated to the limits of the effective radius of the coating material 660. If the substrate 615 exceeds this radius, the sensors 650 may activate the rail 610 and shift the substrate 615 to ensure adequate coating for the entire intended surface of the substrate 615. The rail 610 may allow partial rotation of the substrate 615 to ensure all aspects of an uneven surface are adequately coated. Loss of material may be reduced through preventing coating material 660 transmission before the substrate 615 is in an advantageous position and by using the sensors 650 to ensure the substrate 615 is completely coated and only a minimal amount of coating material 660 is lost as the rail 610 moves the substrate 615.

Referring now to FIG. 7, an exemplary continuous deposition system 700 comprising a replenishing material source 730 and a plurality of sensors 750 is illustrated. In some embodiments, the continuous deposition system 700 may comprise a rail 710. In some aspects, the rail 710 may move to ensure substrate 715 surface areas greater than the effective coating radius of the continuous deposition system 700 are coated sufficiently. In some implementations, the rail 710 may comprise the substrate 715.

In some implementations, the rail 710 may comprise the substrate 715. In some embodiments, particles of the coating material 760 may be excited via electrical terminals 725 that receive power from a power supply 720. In some aspects, the replenishing aspect of the coating material 760 may be facilitated by a controller 735. In some embodiments, the distance between the substrate 715 and the coating material 760 may be determined by one or more sensors 750.

In some embodiments, the continuous deposition system 700 may comprise a rail 710. In some aspects, the rail 710 may move to ensure substrate 715 surface areas greater than the effective coating radius of the continuous deposition system 700 are coated sufficiently. In some embodiments, the rail 710 may translate in linear cardinal directions. For example, the rail 710 may retract from above the coating material 760 to replace a coated substrate 715. The rail 710 may also translate horizontally to ensure the entire intended surface of the substrate 715 is adequately coated. In some implementations, the rail 710 may comprise the substrate 715.

In some aspects, the continuous deposition system 700 may receive coating material 760 from a replenishing material source 730. In some implementations, the charged path of the coating material 760 between the terminals 725 may comprise a series of inclines and declines, as non-limiting examples. This variation in the angle of particle emission may allow uneven surfaces on the substrate to become sufficiently coated with the coating material 760. In some aspects, the height of the inclines and declines may be modified by raising and lower the rods controlling the height. In some embodiments, this may be modified to alter the angle of transmission for uneven substrate 715 surfaces. In some implementations, this modification may be implementation as a result of evaluation of the substrate 715 surface as conducted by the sensors 750.

In some embodiments, particles of the coating material 760 may be excited via electrical terminals 725 that receive power from a power supply 720. In some implementations, the coating material 760 may be replaceable upon depletion in a continuous method. In some aspects, the replenishing aspect of the coating material 760 may be facilitated by a controller 735. In some embodiments, the distance between the substrate 715 and the coating material 760 may be determined by one or more sensors 750.

The sensors 750 may be calibrated to the limits of the effective radius of the coating material 660. If the substrate exceeds this radius, the sensors 750 may activate the rail 710 and shift the substrate 715 to ensure adequate coating for the entire intended surface of the substrate 715. The rail 710 may allow partial rotation of the substrate 715 to ensure all surfaces of an uneven surface are adequately coated.

Loss of material may be reduced through preventing coating material 760 transmission before the substrate 715 is in an advantageous position and by using the sensors to ensure the substrate 715 is completely coated and only a minimal amount of coating material 760 is lost as the rail 710 moves the substrate 715. In some implementations, the rail 710 may comprise a coating that may reject the coating material 760. This may prevent accumulation of material deposition on the continuous deposition system after repeated use. The accumulation prevention may reduce the total loss of material.

In some implementations, the continuous deposition system 700 may comprise a connection between a replenishing material source 730 and a positive terminal. In some aspects, the continuous deposition system 700 may connect the replenishing material source 730 to a negative terminal. In some embodiments, the continuous deposition system 700 may apply voltage from a power supply 720 to a replenishing material source 730, wherein the voltage may pass from the positive terminal to the negative terminal. In some implementations, the continuous deposition system 700 may drive the replenishing material source 730 across the positive terminal and the negative terminal. In some aspects, the continuous deposition system 700 may vaporize at least a portion of the replenishing material source 730 into a coating material 760. In some embodiments, the continuous deposition system 700 may coat a substrate 715 with the coating material, wherein the substrate 715 is located in a predefined proximity to the replenishing material source 730.

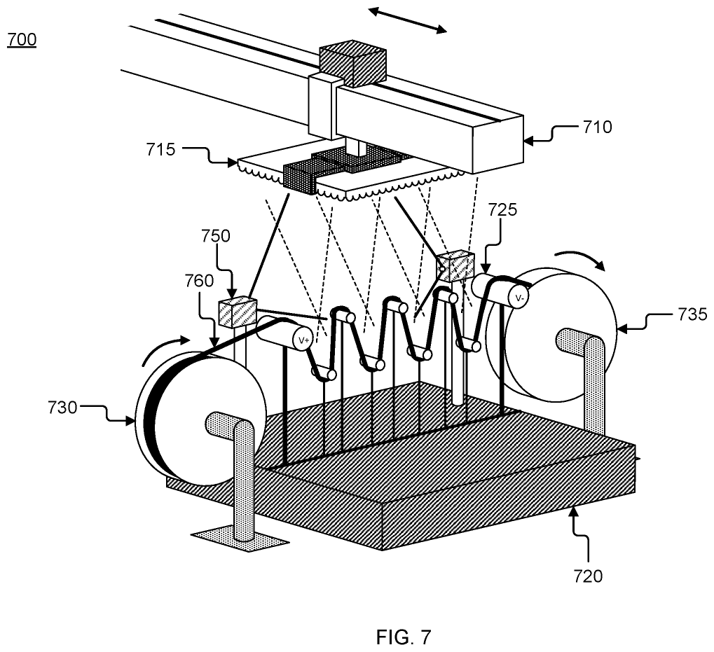

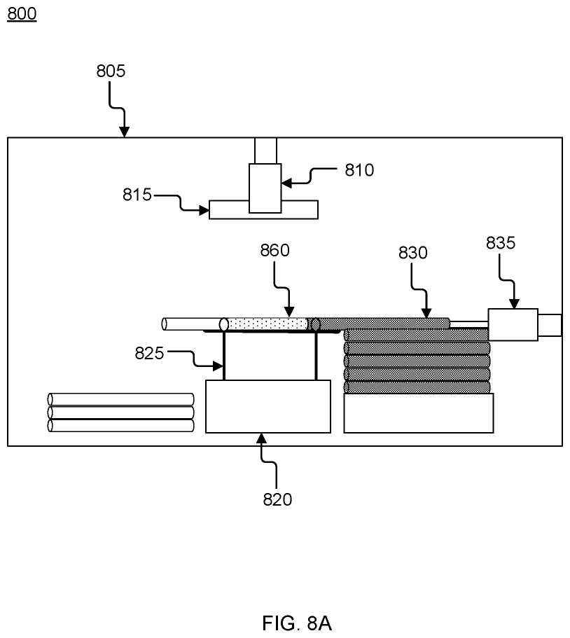

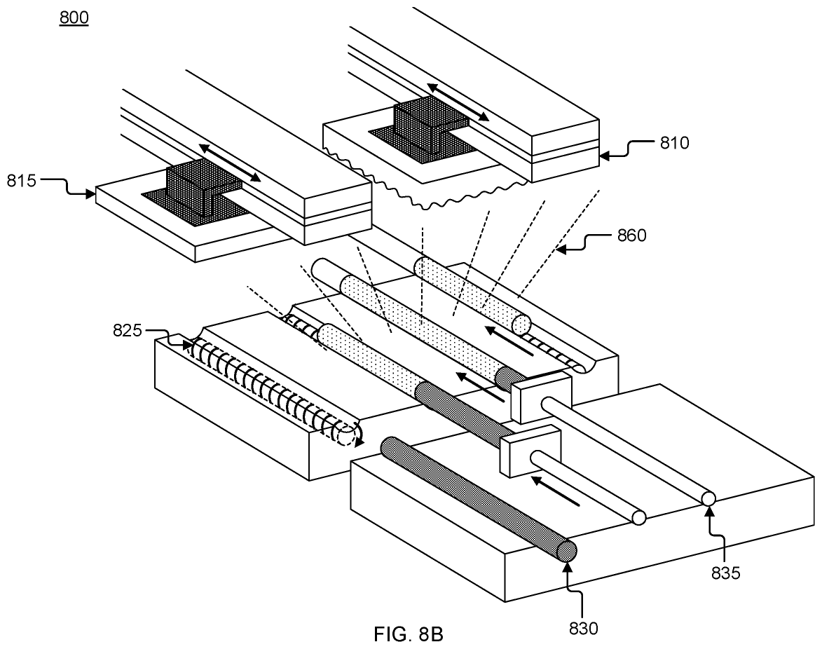

Referring now to FIG. 8, an exemplary continuous deposition system 800 comprising a replenishing material source 830 is illustrated. In some aspects, the replenishing material source 830 may comprise a series of rods that may be continuously replaced within the chamber 805. In some embodiments, a replenishing material source controller 835 may push the replenishing material source 830 through the terminals 825 of a power source 820.

In some implementations, a replenishing material source 830 may comprise a plurality of replenishing material source controllers 835 and rods for coating the substrate 815. In some embodiments, the exemplary continuous deposition system 800 may comprise a plurality of rails 810 that may comprise a plurality of substrate 815. This may allow two or more substrates to be coated simultaneously. In some implementations, the controller 835 may facilitate horizontal translation through a cyclical movement. For example, a lead screw may rotate continuously to move the rods as they transmit the intended coating to the substrate 815.

In some aspects, where the replenishing material source 830 may comprise a series of disconnected pieces, the replenishing material source controller 835 may ensure that each piece connects as they are driven through the terminals 825, which may allow for a consistent electrical current. In some implementations, a substrate 815 may be positioned on a rail 810 that may shift and rotate the substrate 815 as needed to effectively coat the substrate 815. In some aspects, the movement of the substrate 815 may be predefined, such as path, duration, or speed, as non-limiting examples.

In some embodiments, the size of the chamber 805 may be limited, such as by location constraints. For example, a continuous deposition system 800 operating within a manufacturing plant located in space may have different size constraints than a terrestrial location. In some aspects, vaporization and coating requirements may be factors in the size and relative component locations within the chamber 805. For example, vaporized gold molecules easily plate surfaces inside of a vacuum chamber without a significant number of collisions with air molecules interfering with the process.

In some embodiments, the continuous deposition system 800 may comprise a replenishing material source 830, wherein vaporization of at least a portion of the replenishing material source 830 creates a coating material 860. In some implementations, the continuous deposition system 800 may comprise a vaporization mechanism configured to vaporize at least a portion of the replenishing material source 830 into coating material 860.

In some aspects, the continuous deposition system 800 may comprise a controller 835 configured to guide the replenishing material source 830 through the vaporization mechanism. In some embodiments, the continuous deposition system 800 may comprise a power supply 820 configured to power the vaporization mechanism, wherein vaporization is continuous with the power supply 820.

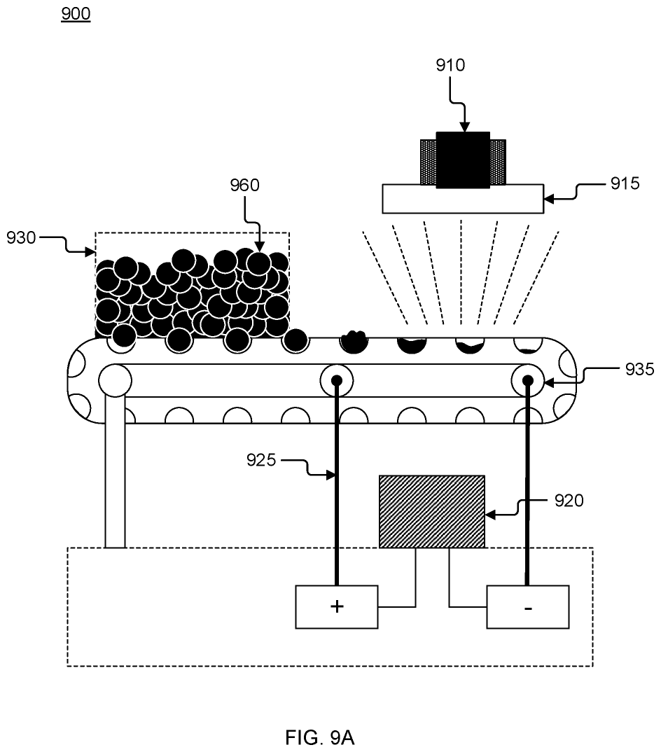

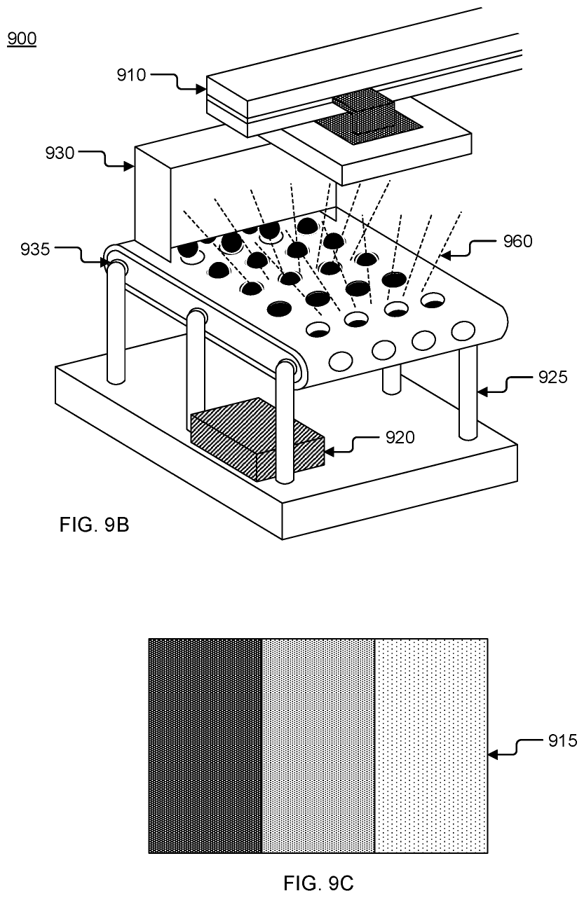

Referring now to FIGS. 9A-9B, an exemplary continuous deposition system 900 comprising a replenishing material source 930 is illustrated. In some embodiments, the continuous deposition system 900 may comprise a rail 910. In some implementations, the rail 910 may comprise the substrate 915. In some aspects, the continuous deposition system 900 may receive coating material 960 from a replenishing material source 930. In some implementations, the replenishing material source 930 may comprise concentrated portions of the coating material 960.

As an illustrative example, the replenishing material source 930 may be a bucket that contains pellets of coating material 960. The distribution of the coating material 960 may be facilitated by a conveyor belt with notches of sufficient size to fit one pellet of coating material 960 at a time. The terminals 925 may power the conveyor belt sufficient to prepare the coating material 960 for transmission. As the coating material 960 approaches the substrate 915, the coating material 960 may begin to coat the substrate 915. The controller 935 may move the conveyor belt at sufficient speed to continuously coat the substrate 915 and deplete the conveyor belt of all coating material 960 by the time the slot containing coating material 960 leaves the effective proximity for coating the substrate 915.

In some embodiments, the replenishing material source 930 may produce a plurality of concentrated coating material 960 simultaneously. In some implementations, the replenishing material source 930 may produce a plurality of concentrated coating material 960 with varying frequency. As an illustrative example, the replenishing material source 930 may produce multiple pellets from a bucket. These pellets may distribute a gradient coating on the substrate 915. The gradient may form by more pellets being transmitted on one end of the controller 935 and less pellets being transmitted on the distal end of the controller 935.

In some embodiments, particles of the coating material may be excited via electrical terminals 925 that receive power from a power supply 920. In some implementations, the coating material 960 may be replaceable upon depletion in a continuous method. For example, the bin containing pellets of coating material 960 may be refilled as it becomes low. This may be done automatically with a sensor within the bin that indicates when the pellets are low and activates the replenishing process. In some aspects, the replenishing aspect of the coating material 960 may be facilitated by a controller 935.

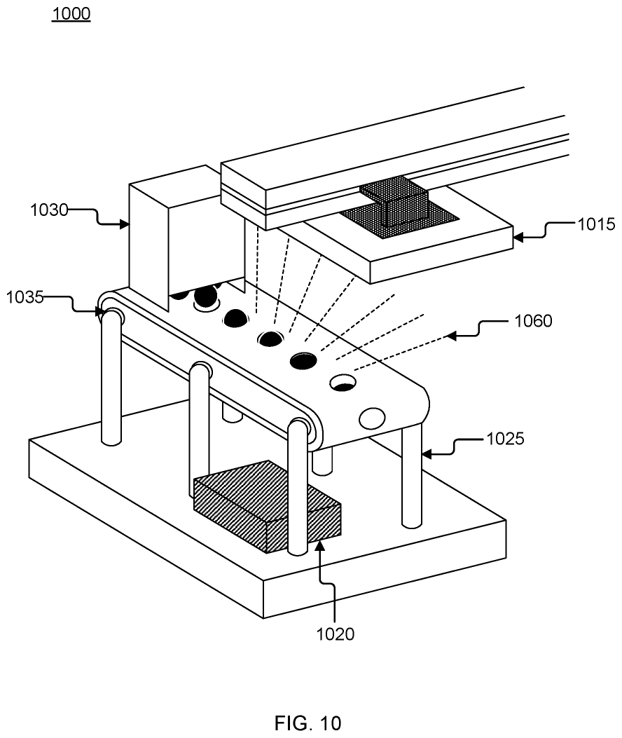

Referring now to FIG. 10, an exemplary continuous deposition system 1000 comprising a replenishing material source 1030 is illustrated. In some aspects, the continuous deposition system 1000 may receive coating material 1060 from a replenishing material source 1030. In some implementations, the replenishing material source 1030 may comprise concentrated portions of the coating material 1060.

As an illustrative example, the replenishing material source 1030 may be a bucket that contains pellets of coating material 1060. The distribution of the coating material 1060 may be facilitated by a conveyor belt with notches of sufficient size to fit one pellet of coating material 1060 at a time. The terminals 1025 may power the conveyor belt sufficient to prepare the coating material 1060 for transmission. As the coating material 1060 approaches the substrate 1015, the coating material 1060 may begin to coat the substrate 1015. The controller 1035 may move the conveyor belt at sufficient speed to continuously coat the substrate 1015 and deplete the conveyor belt of all coating material 1060 by the time the slot containing coating material 1060 leaves the effective proximity for coating the substrate 1015.

In some embodiments, the continuous deposition system 1000 may comprise a replenishing material source 1030, wherein vaporization of at least a portion of the replenishing material source 1030 creates a coating material 1060. In some implementations, the continuous deposition system 1000 may comprise a vaporization mechanism configured to vaporize at least a portion of the replenishing material source 1030 into coating material 1060. In some aspects, the continuous deposition system 1000 may comprise a controller 1035 configured to guide the replenishing material source 1030 through the vaporization mechanism. In some embodiments, the continuous deposition system 1000 may comprise a power supply 1020 configured to power the vaporization mechanism, wherein vaporization is continuous with the power supply 1020.

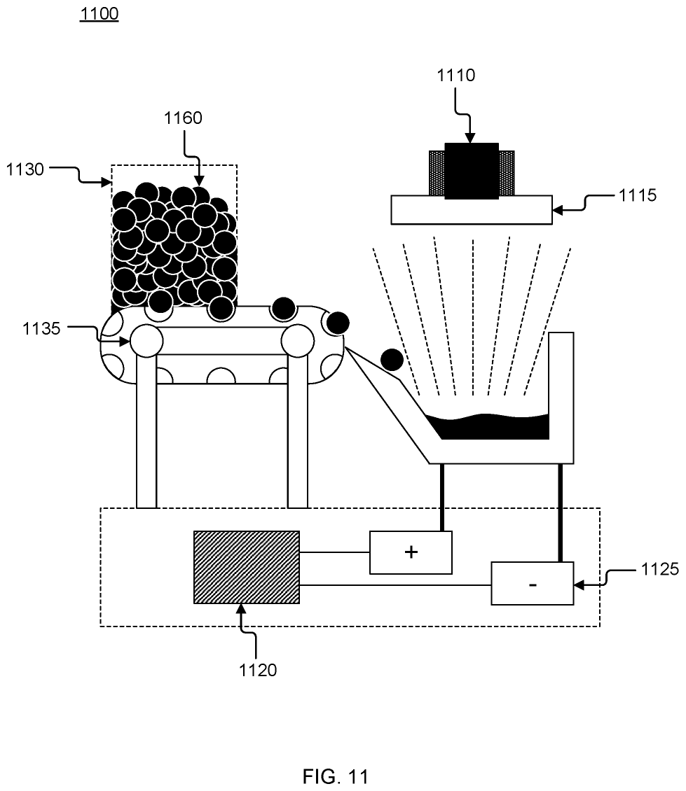

Referring now to FIG. 11, an exemplary continuous deposition system 1100 comprising a replenishing material source 1130 is illustrated. In some embodiments, the continuous deposition system 1100 may comprise a rail 1110. In some implementations, the rail 1110 may comprise the substrate 1115. In some aspects, the continuous deposition system 1100 may receive coating material 1160 from a replenishing material source 1130. In some implementations, the replenishing material source 1130 may comprise concentrated portions of the coating material 1160.

As an illustrative example, the replenishing material source 1130 may be a bucket that contains pellets of coating material 1160. The distribution of the coating material 1160 may be facilitated by a conveyor belt with notches of sufficient size to fit one pellet of coating material 1160 at a time. The power supply 1120 may power the conveyor belt sufficient to relocate the pellets from the replenishing material source 1130 to a basin that may prepare the coating material 1160 for transmission. As the coating material 1160 enters the basin, the terminals 1125 may cause the coating material 1160 to enter a state of transmission. From the basin, the coating material 1160 may begin to coat the substrate 1115. The controller 1135 may move the conveyor belt at sufficient speed to continuously maintain sufficient coating material 1160 within the basin to coat the substrate 1115.

In some embodiments, particles of the coating material 1160 may be excited via electrical terminals 1125 that receive power from a power supply 1120. In some implementations, the coating material 1160 may be replaceable upon depletion in a continuous method. For example, the bin containing pellets of coating material 1160 may be refilled as it becomes low. This may be done automatically with a sensor within the bin that indicates when the pellets are low and activates the replenishing process. In some aspects, the replenishing aspect of the coating material 1160 may be facilitated by a controller 1135.

In some embodiments, the continuous deposition system 1100 may comprise a replenishing material source 1130, wherein vaporization of at least a portion of the replenishing material source 1130 creates a coating material 1160. In some implementations, the continuous deposition system 1100 may comprise a vaporization mechanism configured to vaporize at least a portion of the replenishing material source 1130 into coating material 1160. In some aspects, the continuous deposition system 1100 may comprise a controller 1135 configured to guide the replenishing material source 1130 through the vaporization mechanism. In some embodiments, the continuous deposition system 1100 may comprise a power supply 1120 configured to power the vaporization mechanism, wherein vaporization is continuous with the power supply 1120.

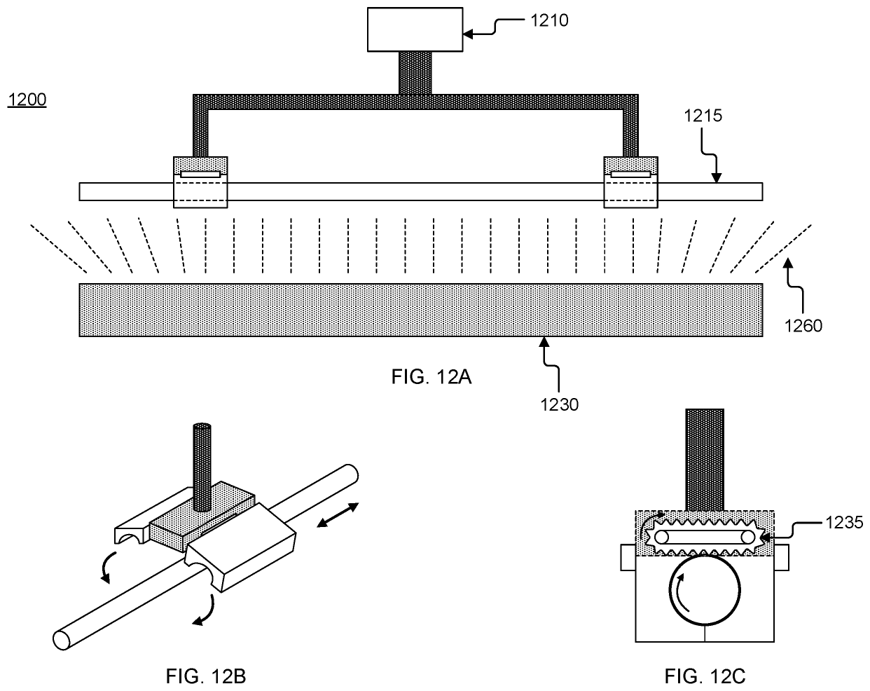

Referring now to FIG. 12A-12C, an exemplary continuous deposition system 1200 comprising a replenishing material source 1230 is illustrated. In some embodiments, the continuous deposition system 1200 may comprise a rail 1210. In some implementations, the rail 1210 may comprise the substrate 1215. In some embodiments, the substrate 1215 may comprise a thin material.

For example, a wire 1215 may be coated as it is rotated by the gears embedded in the rail 1210 and fed through the continuous deposition system 1200. In some aspects, the continuous deposition system 1200 may receive coating material 1260 from a replenishing material source 1230. In some implementations, the replenishing material source 1230 may provide coating material via the rail 1210. For example, the coating material may be dispensed from a tube within the rail 1210 and applied to a wire via direct application.

In some aspects, the application of the coating material may be facilitated by a controller 1235. For example, the coating material may be directly applied to a wire 1215 that is rotated at a predetermined rate by a controller 1235. This may ensure even application of the coating material 1260 as the wire undergoes rotational and translational movement.

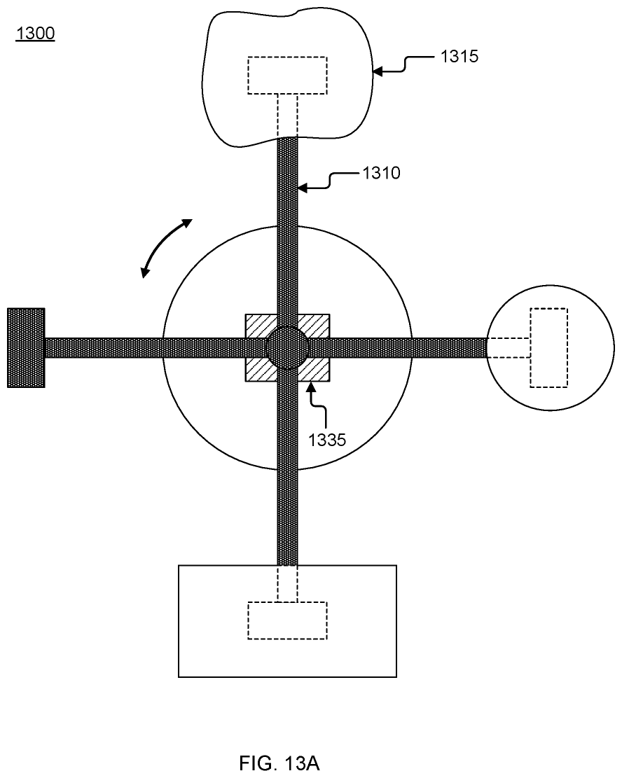

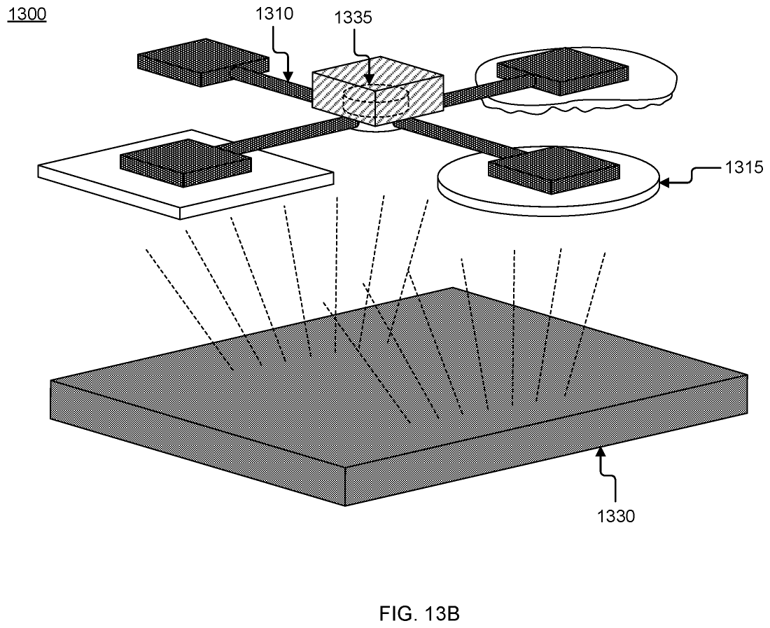

Referring now to FIG. 13A-13B, an exemplary continuous deposition system 1300 comprising a rotational replenishing material source 1330 is illustrated. In some embodiments, the continuous deposition system 1300 may comprise a rail 1310. In some implementations, the replenishing material source 1330 may provide coating material via the rail 1310. For example, the coating material may be dispensed from a tube within the rail 1310 and applied to one or more substrate 1315. In some aspects, the continuous deposition system 1300 may receive coating material from a replenishing material source 1330. In some aspects, the rotational aspect of the continuous deposition system 1300 may be facilitated by a controller 1335.

In some aspects, the application of the coating material may be facilitated by a controller 1335. For example, a sensor may detect the size of the substrate 1315. The controller 1335 may rotate the rail 1310 to a portion of the continuous deposition system 1300 with an adequate radius of coating for the intended substrate 1315. The coating material may be applied from within the rail 1310 to the substrate 1315.

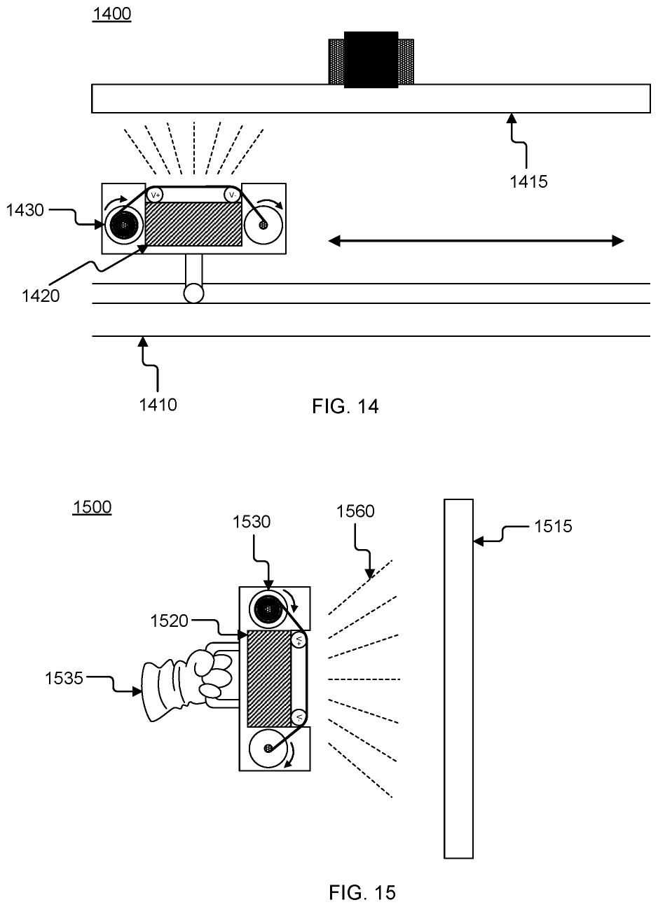

Referring now to FIG. 14, an exemplary continuous deposition system 1400 comprising a large substrate 1415 is illustrated. In some embodiments, the substrate may be fixed. In some implementations the continuous deposition system 1400 may coat the substrate 1415 via a rail 1410. In some aspects, the rail 1410 may comprise sensors that may detect the ends of a large substrate 1415.

In some embodiments, the rail 1410 may comprise one or more axis of movement. In some implementations, the rail may translate vertically and horizontally, as non-limiting directions, to coat a large substrate 1415. In some aspects, the continuous deposition system 1400 may comprise an interchangeable replenishing material source 1430 that may be replaced when depleted. In some embodiments, the continuous deposition system may comprise a portable power supply 1420.

Referring now to FIG. 15, a portable exemplary continuous deposition system 1500 is illustrated. In some embodiments, the substrate 1515 may be fixed. In some implementations the continuous deposition system 1500 may coat the substrate 1515 via manual movement. In some aspects, the continuous deposition system 1500 may comprise sensors that may detect the depletion of a replenishing material source 1530. In some aspects, a portion of the portable continuous deposition system 1500 may be handheld.

For example, spools of coating material 1560 may extend strands of coating material 1560 across terminals that transmit the coating material 1560 to the substrate 1515. In some aspects, the continuous deposition system 1500 may comprise an interchangeable replenishing material source 1530 that may be replaced when depleted. In some embodiments, the continuous deposition system 1500 may comprise a portable power supply 1520.

In some embodiments, the continuous deposition system 1500 may comprise a replenishing material source 1530, wherein vaporization of at least a portion of the replenishing material source 1530 creates a coating material 1560. In some implementations, the continuous deposition system 1500 may comprise a vaporization mechanism configured to vaporize at least a portion of the replenishing material source 1530 into coating material 1560.

In some aspects, the continuous deposition system 1500 may comprise a controller 1535 configured to guide the replenishing material source 1530 through the vaporization mechanism. In some embodiments, the continuous deposition system 1500 may comprise a power supply 1520 configured to power the vaporization mechanism, wherein vaporization is continuous with the power supply 1520.

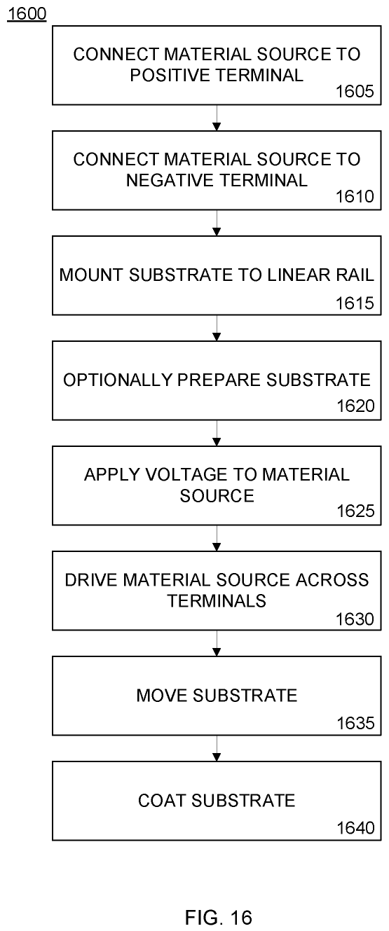

Referring now to FIG. 16, exemplary method steps 1600 for continuous deposition of material onto a substrate are illustrated. At 1605, replenishing material source may be connected to a positive terminal. At 1610, a replenishing material source may be connected to a negative terminal. At 1615, substrate may be mounted to a linear rail. In some aspects, at 1620, the substrate may be prepared, such as by applying an adhesive or wrap, wherein preparation may allow for more uniform or consistent coating. At 1625, voltage may be applied to the replenishing material source. At 1630, replenishing material source may be drive across the terminals. At 1635, substrate may be moved back and forth, and at 1640, the substrate may be coated.

In some implementations, the continuous deposition system may comprise a connection between a replenishing material source and a positive terminal. In some aspects, the continuous deposition system may connect the replenishing material source to a negative terminal. In some embodiments, the continuous deposition system may apply voltage from a power supply to a replenishing material source, wherein the voltage may pass from the positive terminal to the negative terminal.

In some implementations, the continuous deposition system may drive the replenishing material source across the positive terminal and the negative terminal. In some aspects, the continuous deposition system may vaporize at least a portion of the replenishing material source into a coating material. In some embodiments, the continuous deposition system may coat a substrate with the coating material, wherein the substrate is located in a predefined proximity to the replenishing material source.

### CONCLUSION

A number of embodiments of the present disclosure have been described. While this specification contains many specific implementation details, these should not be construed as limitations on the scope of any disclosures or of what may be claimed, but rather as descriptions of features specific to particular embodiments of the present disclosure.

Certain features that are described in this specification in the context of separate embodiments can also be implemented in combination or in a single embodiment. Conversely, various features that are described in the context of a single embodiment can also be implemented in combination in multiple embodiments separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous.

Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described. Other embodiments are within the scope of the following claims. In some cases, the actions recited in the claims can be performed in a different order and still achieve desirable results. In addition, the processes depicted in the accompanying figures do not necessarily require the particular order shown, or sequential order, to achieve desirable results. In certain implementations, multi-tasking and parallel processing may be advantageous. Nevertheless, it will be understood that various modifications may be made without departing from the spirit and scope of the claimed disclosure.

What is claimed is:

1. A system for continuous deposition, the system comprising:
a replenishing material source, wherein vaporization of at least a portion of the replenishing material source creates a coating material;
a vaporization mechanism configured to vaporize at least the portion of the replenishing material source into the coating material;
a controller configured to guide the replenishing material source through the vaporization mechanism; and
a power supply configured to power the vaporization mechanism, wherein vaporization is continuous with the power supply.

2. The system of claim 1, wherein vaporization causes the coating material to coat at least one substrate within a predefined proximity to the replenishing material source.

3. The system of claim 1, further comprising at least one substrate rail configured to maintain a position of the at least one substrate.

4. The system of claim 1, wherein the power supply is further configured to power the controller.

5. The system of claim 1, wherein at least a portion of the system is located within a vacuum environment.

6. The system of claim 1, wherein the coating material comprises a plurality of coating material types.

7. The system of claim 6, wherein the coating of the plurality of coating material types onto at least one substrate comprises a sequence of layering administered to the at least one substrate sequentially.

8. The system of claim 1, wherein the system is mobile.

9. The system of claim 8, wherein the system is handheld.

10. A method for continuous deposition, the method comprising:
connecting a replenishing material source to a positive terminal;
connecting the replenishing material source to a negative terminal;
applying voltage to the replenishing material source, wherein the voltage passes from the positive terminal to the negative terminal;
driving the replenishing material source across the positive terminal and the negative terminal;
vaporizing at least a portion of the replenishing material source into a coating material; and
coating a substrate with the coating material, wherein the substrate is located in a predefined proximity to the replenishing material source.

11. The method of claim 10, wherein the replenishing material source originates from a spool.

12. The method of claim 10, wherein vaporizing the at least the portion of the replenishing material source is continuous with driving the replenishing material source across the positive terminal and the negative terminal.

13. The method of claim 10, further comprising mounting the substrate within the predefined proximity to the replenishing material source.

14. The method of claim 10, wherein coating the substrate occurs at a predefined area of the substrate.

15. The method of claim 14, further comprising moving the substrate to coat the predefined area.

16. The method of claim 10, wherein the vaporization occurs within a vacuum.

17. The method of claim 10, wherein one or both connecting to the positive terminal and connecting to the negative terminal occur indirectly.

18. The method of claim 10, wherein one or both connecting to the positive terminal and connecting to the negative terminal occur directly.

19. The method of claim 10, further comprising replenishing the replenishing material source.

20. The method of claim 19, wherein replenishing the replenishing material source is continuous.
